(19) United States
(12) Patent Application Publication
(10) Pub. No.: US 2025/0366083 A1
(43) Pub. Date: Nov. 27, 2025

(54) SON DEVICE AND MANUFACTURING METHOD THEREOF

(71) Applicant: Hangzhou HFC Semiconductor Co., Hangzhou (CN)

(72) Inventors: Pengpeng Wang, Hangzhou (CN); Fanyou Kong, Hangzhou (CN); Qiangtao Zhu, Hangzhou (CN); Tao Wang, Hangzhou (CN); John H Zhang, Altamont, NY (US)

(21) Appl. No.: 18/743,491

(22) Filed: Jun. 14, 2024

(30) Foreign Application Priority Data
May 24, 2024 (CN) 202410650205.8

(51) Int. Cl. H01L 29/06; H01L 21/02; H01L 21/311; H01L 21/762; H01L 21/764; H01L 29/66; H01L 29/78

(52) U.S. Cl. CPC H10D 62/102; H01L 21/02238; H01L 21/31116; H01L 21/76232; H01L 21/764; H10D 30/022; H10D 30/601; H10D 62/124

(57) ABSTRACT

A silicon-on-nothing (SON) device and a method for fabricating the SON device are disclosed. The method includes: providing a semiconductor substrate; forming a trench in the semiconductor substrate, the trench having first and second sidewalls; forming a dielectric layer lining the trench and covering a surface of the semiconductor substrate, the dielectric layer comprising stacked first and second dielectric layers; filling the trench with a decomposable material layer; etching back the decomposable material to remove portions of the decomposable material and the dielectric layer on the first sidewalls, exposing portions of the first sidewalls; performing an epitaxial growth process to grow, on the exposed first sidewalls, an epitaxial layer which completely fills the trench; removing the second dielectric layer using a wet etching process, forming a gap extending along the second sidewalls of the trench; and vaporizing away the remaining decomposable material layer along the gap, thereby forming a cavity.

### CROSS-REFERENCE TO RELATED APPLICATION

This application claims the priority of Chinese patent application number 202410650205.8, filed on May 24, 2024 and entitled “SON DEVICE AND METHOD FOR FABRICATING SAME”, the entire contents of which are incorporated herein by reference.

### TECHNICAL FIELD

The present invention relates to the field of semiconductor technology and, in particular, to a silicon-on-nothing (SON) device and a method for fabricating the SON device.

### BACKGROUND

As transistors continue to shrink, their power consumption and leakage current problems are attracting more and more attention. The silicon-on-insulator (SOI) architecture has been preferred by deep-submicron transistor devices because it can desirably suppress short channel effects and allows proportional scaling-down of the devices.

As the SOI technology continues to advance, researchers have developed silicon-on-nothing (SON) transistors. Such transistor has a “cavity”, which allows local SOI to be formed under a channel. SON devices provide improved performance over SOI devices because they exhibit reduced source-to-drain coupling through the buried oxide layer and can effectively suppress drain-induced barrier lowering (DIBL) effects.

For the fabrication of an SON device, the formation of such a hollow cavity is most crucial. As conventional SON device fabrication processes are still complicated, there is an urgent need to develop a method capable of easy fabrication of an SON device.

### SUMMARY OF THE INVENTION

It is an object of the present invention to provide an SON device and a method for fabricating the device, which overcome the prior-art problem of complicated SON device fabrication.

To this end, the present invention provides a method for fabricating an SON device, comprising:
providing a semiconductor substrate;
forming at least one trench in the semiconductor substrate, wherein the trench has first sidewalls and second sidewalls;
forming a dielectric layer, wherein the dielectric layer lines the trench and extends over a surface of the semiconductor substrate, and wherein the dielectric layer comprises stacked first and second dielectric layers;
filling the trench with a decomposable material layer;
etching back the decomposable material layer to remove a portion of the decomposable material layer and a portion of the dielectric layer formed on the first sidewalls, exposing portions of the first sidewalls;
performing an epitaxial growth process to grow an epitaxial layer on the exposed portions of the first sidewalls, wherein the epitaxial layer completely fills the trench;
removing the second dielectric layer using a wet etching process, forming a gap extending along the second sidewalls of the trench; and
forming a cavity by vaporizing away a remaining portion of the decomposable material layer along the gap.

The present invention further provides an SON device comprising:
a semiconductor substrate; and
an epitaxial layer formed in the semiconductor substrate, the epitaxial layer and the semiconductor substrate delimits a cavity, wherein the cavity is covered with a first dielectric layer at its bottom and sidewalls.

In the SON device and method of the present invention, the decomposable material layer is filled in the trench and then vaporized away after the epitaxial layer is formed thereon. In this way, the cavity can be formed in a simpler way.

### BRIEF DESCRIPTION OF THE DRAWINGS

FIGS. 1 to 22 show schematic cross-sectional views of intermediate structures resulting from process steps in a method for fabricating an SON device according to embodiments of the present invention, taken along a first extension direction.

FIGS. 23 to 27 show schematic cross-sectional views of intermediate structures resulting from process steps in a method for fabricating an SON device according to embodiments of the present invention, taken along a second extension direction.

### LIST OF REFERENCE NUMERALS

100—semiconductor substrate; 101—well region; 110—first isolation structure; 111—second isolation structure; 120—first patterned mask layer; 130—trench; 131—first sidewall; 132—second sidewall; 140—dielectric layer; 141—first dielectric layer; 142—second dielectric layer; 150—decomposable material layer; 160—second patterned mask layer; 170—epitaxial layer; 180—gap; 190—cavity; 191—third sidewall; 200—gate structure; 201—gate dielectric layer; 202—gate conductive layer; 210—lightly-doped source region; 211—lightly-doped drain region; 220—spacer; 230—source region; 231—drain region;
T1—first extension direction; T2—second extension direction; L1—first cross-sectional width; L2—second cross-sectional width; H1—junction depth; H2—distance.

### DETAILED DESCRIPTION

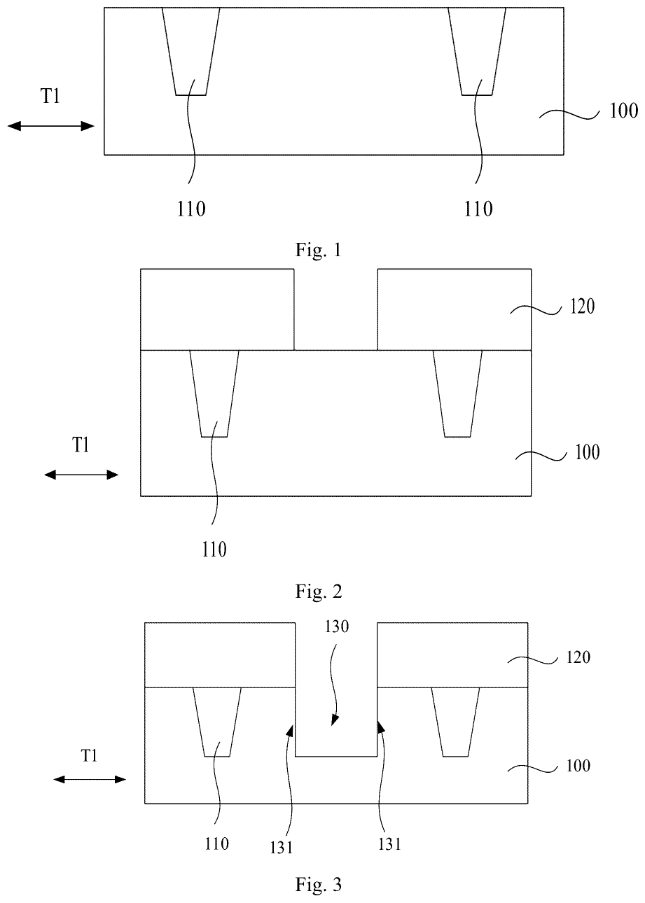

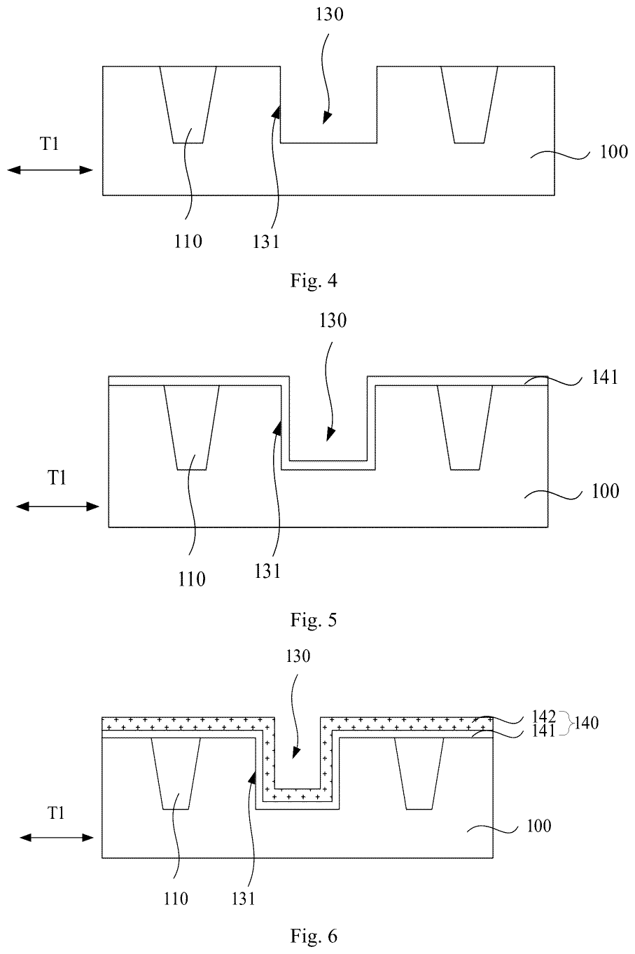

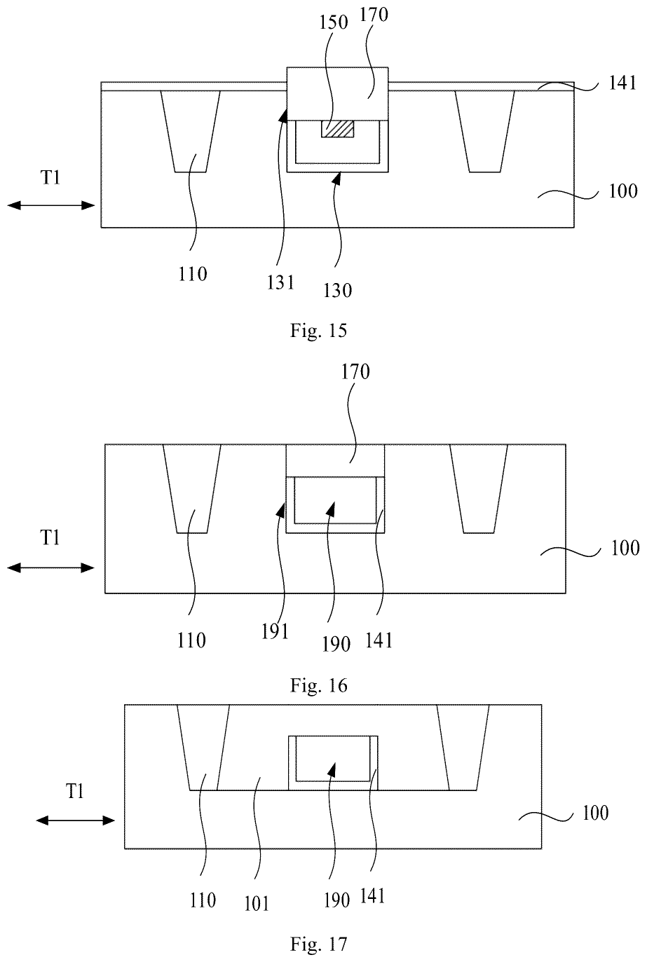

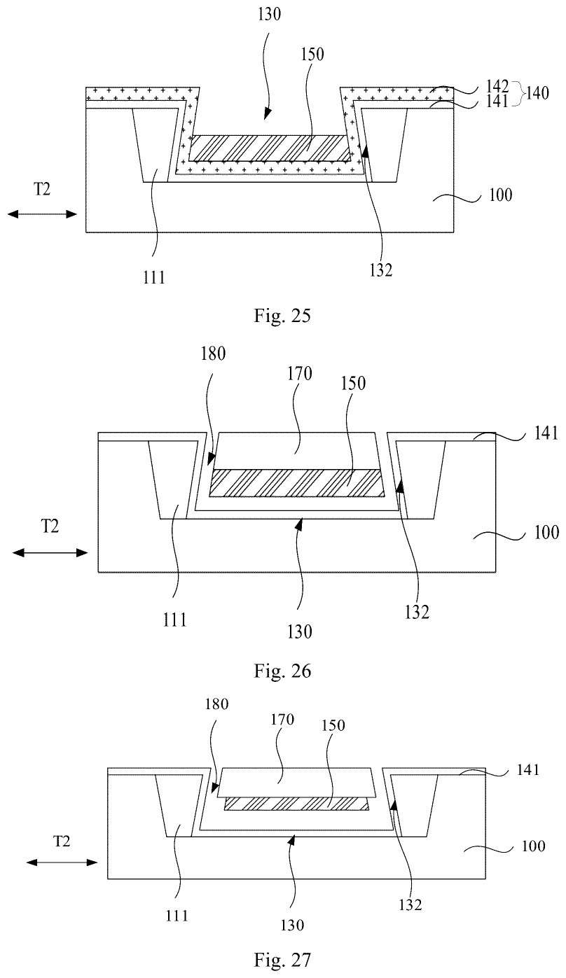

Reference is made to FIGS. 1 to 25. FIGS. 1 to 22 show schematic cross-sectional views of intermediate structures resulting from process steps in a method for fabricating a silicon-on-nothing (SON) device according to embodiments of the present invention, taken along a first extension direction. FIGS. 23 to 27 show schematic cross-sectional views of intermediate structures resulting from process steps in a method for fabricating an SON device according to embodiments of the present invention, taken along a second extension direction. FIG. 23 corresponds to FIG. 1, FIG. 24 corresponds to FIG. 4, FIG. 25 corresponds to FIG. 11, FIG. 26 corresponds to FIG. 14 and FIG. 27 corresponds to FIG. 15.

As shown in FIGS. 1 and 23, a semiconductor substrate 100 is provided. According to an embodiment of the present application, the semiconductor substrate 100 is a silicon substrate. In particular, the semiconductor substrate 100 may be a bulk silicon substrate.

In the semiconductor substrate 100, first isolation structures 110 and second isolation structures 111 are formed. The first isolation structures 110 are arranged along a first extension direction T1 of the semiconductor substrate 100, and the second isolation structures 111 are arranged along a second extension direction T2 of the semiconductor substrate 100. In the schematic drawings, two first isolation structures 110 and two second isolation structures 111 are shown, which together delimit one device region there between.

In the following, description and illustration are made based mainly on the first extension direction T1, and illustration is further facilitated based on the second extension direction T2.

As shown in FIG. 2, a first patterned mask layer 120 is formed on the semiconductor substrate 100, and a portion of the semiconductor substrate 100 is exposed from the first patterned mask layer 120.

Next, as shown in FIG. 3, the exposed portion of the semiconductor substrate 100 is etched to form a trench 130 therein. According to an embodiment of the present application, the trench 130 is as deep as the first isolation structures 110 and the second isolation structures 111. In other embodiments of the present application, the trench 130 may be deeper or shallower than the first isolation structures 110 and the second isolation structures 111.

Referring to FIGS. 4 and 24, the first patterned mask layer 120 is removed. In particular, the first patterned mask layer 120 may be removed by ashing.

As shown in FIG. 4, the trench 130 has opposite first sidewalls 131, and the first sidewalls 131 are spaced apart from the first isolation structures 110. In the illustrated embodiment, the first sidewalls 131 are perpendicular to a surface of the semiconductor substrate 100.

As shown in FIG. 24, the trench 130 has opposite second sidewalls 132, and the second sidewalls 132 are coincident with the sidewalls of the second isolation structures 111. In the illustrated embodiment, the second sidewalls 132 are inclined with respect to the surface of the semiconductor substrate 100.

Next, as shown in FIGS. 5 and 6, a dielectric layer 140 is formed. The dielectric layer 140 lines the trench 130 and extends over the surface of the semiconductor substrate 100. According to an embodiment of the present application, the dielectric layer 140 includes a first dielectric layer 141 and a second dielectric layer 142, which are stacked together. Specifically, as shown in FIG. 5, at first, the first dielectric layer 141 is formed to line the trench 130 and extend over the surface of the semiconductor substrate 100. For example, the first dielectric layer 141 may be made of an oxide. In particular, the first dielectric layer 141 may be formed by an oxidation process.

Subsequently, as shown in FIG. 6, the second dielectric layer 142 is formed on the first dielectric layer 141. The second dielectric layer 142 is made of a material different from a material of the first dielectric layer 141. In the illustrated embodiment, the second dielectric layer 142 is etched faster than the first dielectric layer 141. According to an embodiment of the present application, the second dielectric layer 142 is made of a nitride. Preferably, the second dielectric layer 142 has a thickness ranging from 5 nm to 20 nm. That is, the thickness of the second dielectric layer 142 is greater than or equal to 5 nm and less than or equal to 20 nm. Such a thickness allows subsequent formation of a suitable gap. The second dielectric layer 142 may be formed by a deposition process.

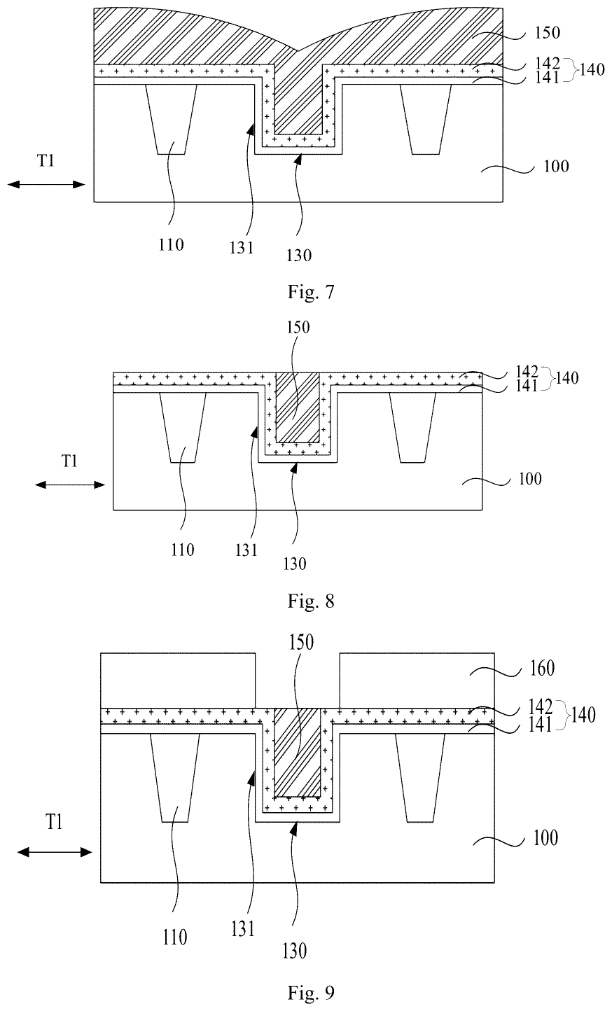

Referring to FIG. 7, according to an embodiment of the present application, a decomposable material layer 150 is then deposited. The decomposable material layer 150 fills the trench 130 and extends over the dielectric layer 140 outside the trench 130. The decomposable material layer 150 may be any material that can be decomposed under the action of external energy such as photons, an e-beam or the like.

After that, as shown in FIG. 8, a polishing process is performed on the decomposable material layer 150 to remove the decomposable material layer 150 outside the trench 130, thereby filling the trench 130 with the decomposable material layer 150 and exposing the dielectric layer 140 outside the trench 130.

Referring to FIG. 9, according to an embodiment of the present application, a second patterned mask layer 160 is formed on the dielectric layer 140. The decomposable material layer 150 is exposed from second patterned mask layer 160.

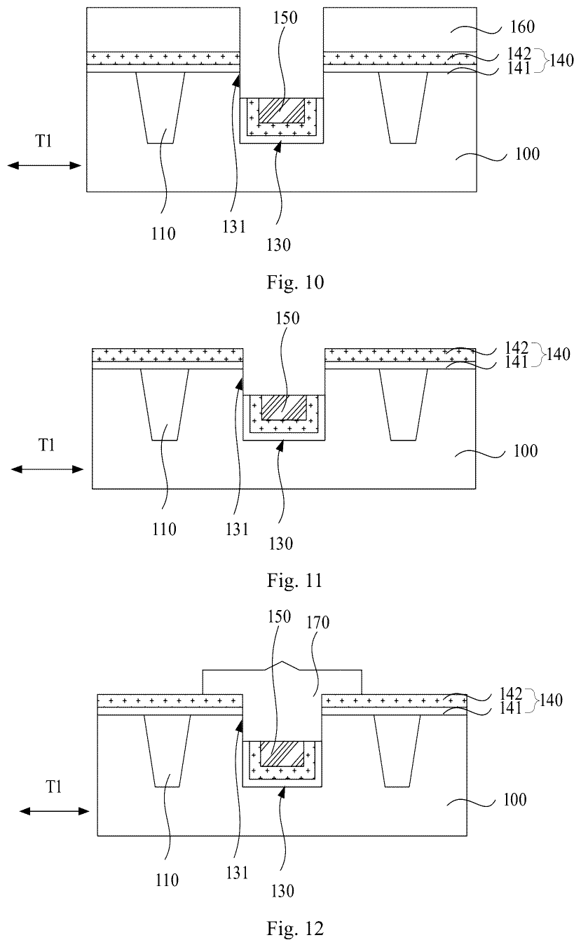

Afterwards, as shown in FIG. 10, an etch-back process is performed to remove a portion of the decomposable material layer 160. According to an embodiment of the present application, in this process, the dielectric layer 140 on the first sidewalls 131 is also partially etched away, exposing part of the first sidewalls 131. In the illustrated embodiment, the top of the remaining decomposable material layer 150 is flush with the top of the dielectric layer 140 remaining on the first sidewalls 131.

After that, the second patterned mask layer 160 is removed. In particular, the second patterned mask layer 160 may be removed by ashing.

Referring to FIGS. 11 and 25, in the first extension direction T1, portions of the first sidewalls 131 of the trench 130 are exposed; while in the second extension direction T2, the dielectric layer 140 still covers the second sidewalls 132 of the trench 130.

Subsequently, as shown in FIG. 12, an epitaxial layer 170 is grown on the exposed first sidewalls 131 until it completely fills the trench 130. In the illustrated embodiment, the epitaxial layer 170 is an epitaxial silicon layer, and the epitaxial layer 170 completely fills the trench 130 and extends outside the trench 130.

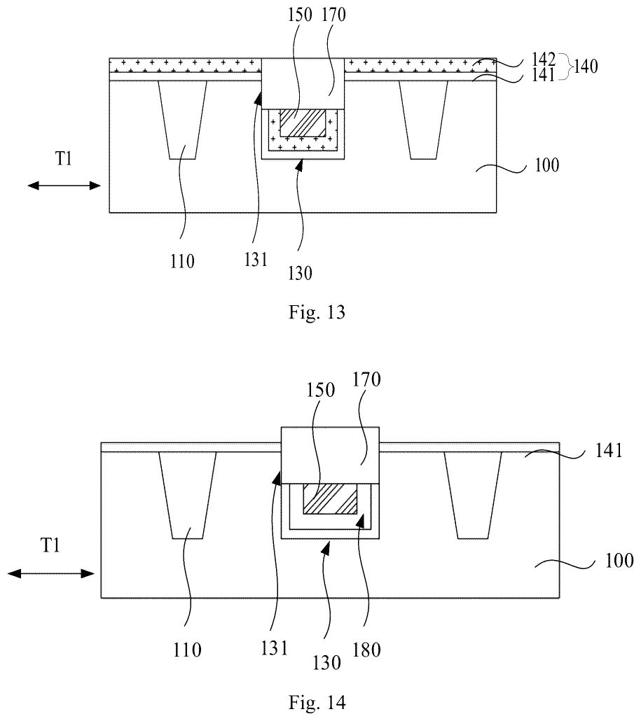

Referring to FIG. 13, according to an embodiment of the present application, the epitaxial layer 170 is then polished and planarized. In particular, the epitaxial layer 170 outside the trench 130 may be removed by a chemical mechanical polishing (CMP) process, while the remaining portion of the epitaxial layer 170 still completely fills the trench 130.

Referring to FIGS. 14 and 26, the second dielectric layer 142 is removed using a wet etching process, forming a gap 180 extending along the second sidewalls 132 of the trench 130. Specifically, in the wet etching process, the second dielectric layer 142 above the surface of the semiconductor substrate 100 is first eroded away and then the second dielectric layer 142 above the second sidewalls 132 of the trench 130 is eroded away, thereby resulting in the formation of the gap 180. The gap 180 is delimited by the second sidewalls 132, the bottom and the first sidewalls 131 of the trench 130.

Referring to FIGS. 15, 16 and 27, thereafter, the remaining decomposable material layer 150 is vaporized away along the gap 180, forming a cavity 190. In particular, the vaporization may be accomplished with ultraviolet (UV) radiation, X-rays, infrared (IR) radiation, visible light, an e-beam or another form of energy. As a result of decomposition of the decomposable material layer 150, the cavity 190 is formed. In the process of vaporization, the decomposable material layer 150 may vaporize through the gap 180, resulting in the cavity 190 being delimited by the semiconductor substrate 100 and the epitaxial layer 170. Further, monitoring the vaporization of gas at the gap 180 to control the vaporization process.

Referring to FIG. 16, in conjunction with FIG. 27, the cavity 190 has third sidewalls 191 (defined by portions of the first sidewalls 131) spaced apart from the first isolation structures 110 in the first extension direction T1. The cavity 190 also has fourth sidewalls (defined by portions of the second sidewalls 132, not shown) coincide with the sidewalls of the second isolation structures 111 in the second extension direction T2. The bottom and sidewalls of the cavity 190 are lined with the first dielectric layer 141. That is, the first dielectric layer 141 covers the bottom, the third sidewalls 191 and the fourth sidewalls of the cavity 190.

According to embodiments of the present application, through filling the trench 130 with the decomposable material layer 150 and vaporizing it away after the epitaxial layer 170 is formed thereon, the cavity 190 can be formed in a simpler way.

Referring to FIG. 17, subsequent to the formation of the cavity 190, ions are implanted into the semiconductor substrate 100 to form a well region 101 in the semiconductor substrate 100 and in the epitaxial layer 170.

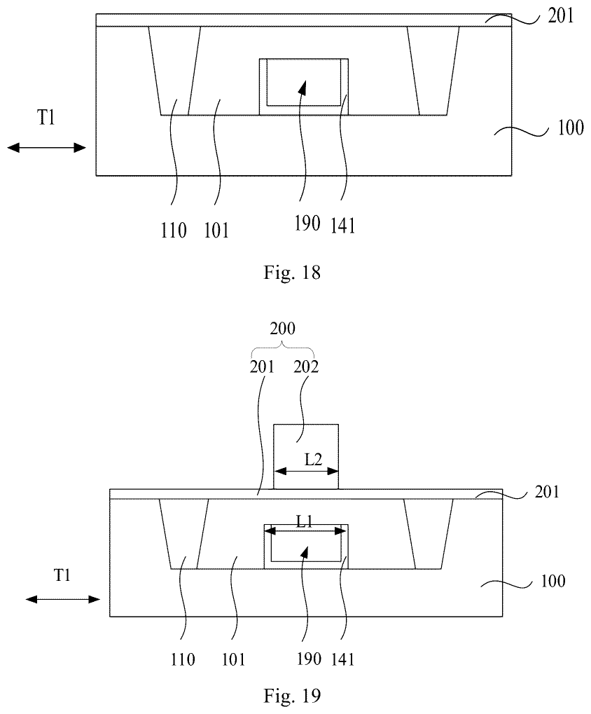

Subsequently, as shown in FIG. 18, a gate dielectric layer 201 is formed, which covers the epitaxial layer 170 and the semiconductor substrate 100.

Referring to FIG. 19, a gate conductive layer 202 is formed on the gate dielectric layer 201, thus forming a gate structure 200 on the semiconductor substrate 100. In the illustrated embodiment, the gate conductive layer 202 is made of polysilicon, for example. With continued reference to FIG. 19, the gate structure 200 is aligned with the cavity 190, and in the first extension direction T1, a first cross-sectional width L1 of the cavity 190 is greater than a second cross-sectional width L2 of the gate structure 200.

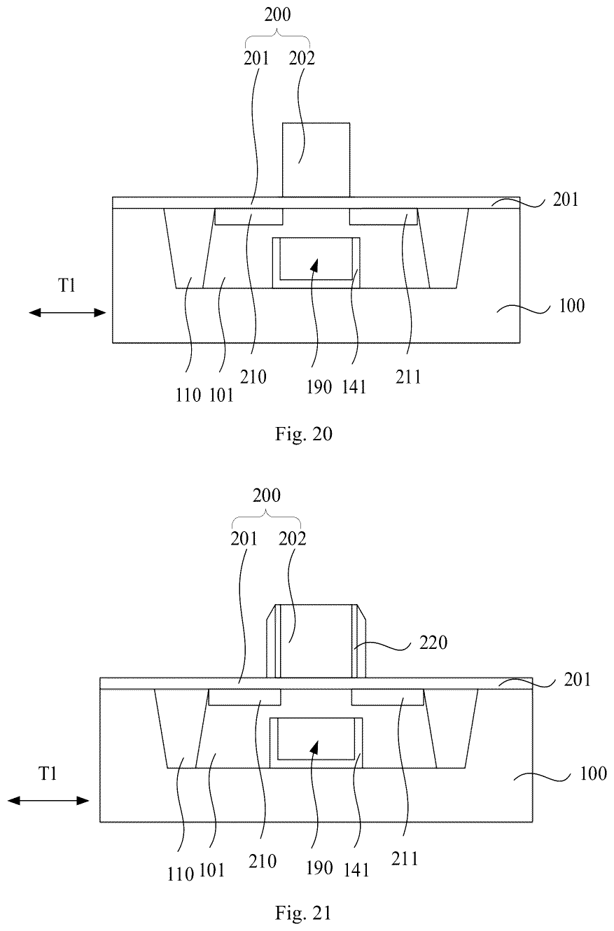

As shown in FIG. 20, ions are implanted into the well region 101 to form a lightly-doped source region 210 and a lightly-doped drain region 211.

Afterwards, as shown in FIG. 21, spacers 220 are formed on opposite sidewalls of the gate structure 200. The spacers 220 may be single-layer structure or multilayer structure.

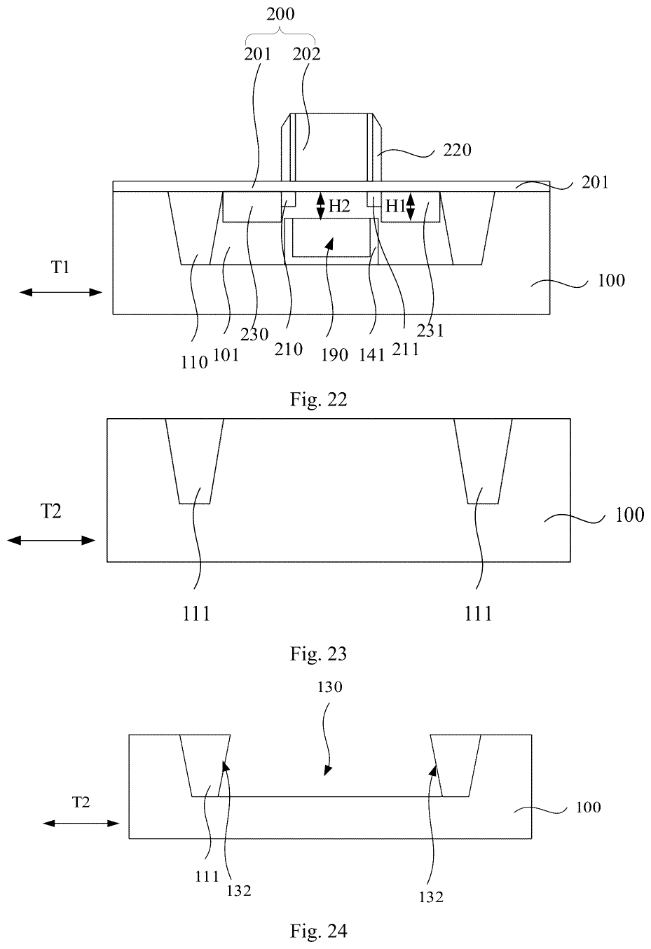

As shown in FIG. 22, ions are further implanted into the well region 101 to form a source region 230 and a drain region 231. According to an embodiment of the present application, the source region 230 and/or the drain region 231 may have a junction depth H1 greater than a distance H2 measured from the top of the cavity 190 to the surface of the semiconductor substrate 100 (or measured from the top of the cavity 190 to a surface of the epitaxial layer 170). Further, the distance H2 from the top of the cavity 190 to the surface of the semiconductor substrate 100 is greater than 0.01 μm.

With continued reference to FIG. 22, in embodiments of the present invention, there is also provided an SON device, which includes: a semiconductor substrate 100; and an epitaxial layer 170 located in the semiconductor substrate 100, the epitaxial layer 170 together with the semiconductor substrate 100 delimits a cavity 190, and the cavity 190 is covered by a first dielectric layer 141 at its bottom and sidewalls.

The SON device further includes a gate structure 200 formed on the semiconductor substrate 100. The gate structure 200 is aligned with the cavity 190, and in a first extension direction T1, the cavity 190 has a first cross-sectional width L1 greater than a second cross-sectional width L2 of the gate structure 200. A well region 101 is formed in the semiconductor substrate 100 and the epitaxial layer 170. In the well region 101, there are formed a lightly-doped source region 210, a lightly-doped drain region 211, a source region 230 and a drain region 231. A distance H2 measured from the top of the cavity 190 to a surface of the semiconductor substrate 200 is greater than 0.01 μm and less than a junction depth H1 of the source region 230 or of the drain region 231.

In the SON device and method of the present invention, the decomposable material layer 150 is filled in the trench 130 and then vaporized away after the epitaxial layer 170 is formed thereon. In this way, the cavity 190 can be formed in a simpler way. Further, the resulting SON device can effectively suppress DIBL effects and provide good performance.

The description presented above is merely that of some preferred embodiments of the present invention and is not intended to limit the scope thereof in any sense. Any and all changes and modifications made by those of ordinary skill in the art based on the above teachings fall within the scope of the invention.

1. A method for fabricating a silicon-on-nothing (SON) device, comprising:
providing a semiconductor substrate;
forming at least one trench in the semiconductor substrate, wherein the trench comprises first sidewalls and second sidewalls;
forming a dielectric layer, wherein the dielectric layer lines the trench and extends over a surface of the semiconductor substrate, and wherein the dielectric layer comprises a stack of a first dielectric layer and a second dielectric layer;
filling the trench with a decomposable material layer;
etching back the decomposable material layer to remove a portion of the decomposable material layer and portions of the dielectric layer formed on the first sidewalls, exposing portions of the first sidewalls;
performing an epitaxial growth process to grow an epitaxial layer on the exposed portions of the first sidewalls, wherein the epitaxial layer completely fills the trench;
forming a gap extending along the second sidewalls of the trench by removing the second dielectric layer through a wet etching process; and
forming a cavity by vaporizing away a remaining portion of the decomposable material layer along the gap.

2. The method of claim 1, wherein the decomposable material layer is a material decomposable by photons or an e-beam.

3. The method of claim 2, wherein the vaporization is accomplished with ultraviolet (UV) radiation, X-rays, infrared (IR) radiation, visible light or an e-beam.

4. The method of claim 1, wherein the semiconductor substrate is a silicon substrate, wherein the substrate is provided with first isolation structures and second isolation structures, wherein the first isolation structures are arranged along a first extension direction of the semiconductor substrate, and wherein the second isolation structures are arranged along a second extension direction of the semiconductor substrate.

5. The method of claim 4, wherein a third sidewall of the cavity is spaced apart from a sidewall of the first isolation structure in the first extension direction, and wherein a fourth sidewall of the cavity is coincident with a sidewall of the second isolation structure in the second extension direction.

6. The method of claim 4, further comprising:
forming a gate structure on the semiconductor substrate, wherein the gate structure is aligned with the cavity, and wherein in the first extension direction, a first cross-sectional width of the cavity is greater than a second cross-sectional width of the gate structure.

7. The method of claim 6, further comprising: before the gate structure is formed on the semiconductor substrate, forming a well region in the semiconductor substrate and in the epitaxial layer; and
after the gate structure is formed on the semiconductor substrate, forming: a lightly-doped source region and a lightly-doped drain region in the well region; and forming a source region and a drain region in the well region.

8. The method of claim 7, wherein a distance from a top of the cavity to the surface of the semiconductor substrate is greater than 0.01 μm and is less than a junction depth of the source region or a junction depth of the drain region.

9. The method of claim 1, wherein the first dielectric layer is made of an oxide and the second dielectric layer is made of a nitride.

10. A silicon-on-nothing (SON) device, comprising:
a semiconductor substrate; and
an epitaxial layer formed in the semiconductor substrate, wherein the epitaxial layer and the semiconductor substrate delimits a cavity, and wherein the cavity is covered with a first dielectric layer at a bottom and sidewalls thereof.

11. The SON device of claim 10, further comprising, a gate structure formed on the semiconductor substrate, wherein the gate structure is aligned with the cavity, and wherein in a first extension direction, a first cross-sectional width of the cavity is greater than a second cross-sectional width of the gate structure.

12. The SON device of claim 10, further comprising, a well region that is formed in the semiconductor substrate and in the epitaxial layer.

13. The SON device of claim 12, further comprising: a lightly-doped source region and a lightly-doped drain region formed in the well region; and a source region and a drain region formed in the well region.

14. The SON device of claim 13, wherein a distance from a top of the cavity to a surface of the semiconductor substrate is greater than 0.01 μm and is less than a junction depth of the source region or a junction depth of the drain region.

15. The SON device of claim 10, wherein the first dielectric layer is made of an oxide.
